(19) United States
(12) Patent Application Publication
(10) Pub. No.: US 2026/0230064 A1
(43) Pub. Date: Aug. 6, 2026

(54) CLOCK LATCH WITH INTEGRATED TEST SIGNAL

(71) Applicant: Advanced Micro Devices, Inc., Santa Clara, CA (US)

(72) Inventors: Deepesh John, Austin, TX (US); Sundararajan Rangarajan, Austin, TX (US); Teja Singh, Austin, TX (US); Christopher S. Oliver, Austin, TX (US); Kunal Garg, Austin, TX (US); Nitin Kumar, Austin, TX (US); Siddhesh Mhambrey, Austin, TX (US); Shravan Lakshman, Austin, TX (US)

(21) Appl. No.: 19/043,291

(22) Filed: Jan. 31, 2025

(51) Int. Cl. H03K 3/037; G01R 31/317; H03K 19/20

(52) U.S. Cl. CPC H03K 3/037; G01R 31/31727; H03K 19/20

(57) ABSTRACT

In an implementation, a clock latch system may include a front-end circuit configured to receive and process input signals. The clock latch system may also include a latch circuit connected to the front-end circuit and configured to store a state of a processed signal. The clock latch system may also include an output driver circuit connected to the latch circuit. The clock latch system may also include test enable signals coupled to at least one of the latch circuit or the output driver circuit. The clock latch system may also include a clock generation circuit connected to the latch circuit.

### BACKGROUND

Clock latches are fundamental components in modern digital circuit design, contributing to the timing and synchronization of data flow within integrated circuits. These elements are used in various applications, from high-performance microprocessors to low-power mobile devices, and function as part of sequential logic circuits. Clock latches operate by capturing and holding data at specific time intervals, as determined by a clock signal, facilitating orderly data propagation through complex digital systems.

In modern integrated circuit design, clock latches must not only meet stringent timing requirements but also incorporate additional functionalities such as test and scan capabilities. These features can help verify the correct operation of complex circuits during manufacturing and debugging processes. However, integrating these additional functions while maintaining optimal performance and power efficiency presents significant challenges for circuit designers.

### BRIEF DESCRIPTION OF THE DRAWINGS

For a more complete understanding of the present invention, and the advantages thereof, reference is now made to the following descriptions taken in conjunction with the accompanying drawings.

FIG. 1 illustrates a block diagram of a clock latch system with integrated test signals, in accordance with some implementations.

FIG. 2 illustrates a circuit diagram of a clock latch system with a logic front-end, in accordance with some implementations.

FIG. 3 illustrates a circuit diagram of a clock latch system with a modified clock generation circuit, in accordance with some implementations.

FIG. 4 illustrates a detailed circuit diagram of a clock latch with a modified output driver, in accordance with some implementations.

FIG. 5 illustrates a block diagram of a clock latch system with test inputs to the latch circuit, in accordance with some implementations.

FIG. 6 illustrates a circuit diagram of a clock latch with integrated SSE test functionality, in accordance with some implementations.

FIG. 7 illustrates a circuit diagram of a clock latch system with an advanced clock generation circuit, in accordance with some implementations.

FIG. 8 illustrates a circuit diagram of a clock latch with multiple test signal inputs, in accordance with some implementations.

FIG. 9 illustrates a detailed circuit diagram of a clock latch system with complex test signal integration, in accordance with some implementations.

FIG. 10 illustrates a circuit diagram of a clock latch system with a modified output driver, in accordance with some implementations.

FIG. 11 illustrates a circuit diagram of a clock latch system with pre-latched test enable inputs, in accordance with some implementations.

FIG. 12 illustrates a flowchart of a method for operating a clock latch system, in accordance with some implementations.

FIG. 13 illustrates a flowchart of a method for operating a clock latch system, in accordance with some implementations.

FIG. 14 illustrates a flowchart of a method for operating a clock latch system, in accordance with some implementations.

Corresponding numerals and symbols in the different figures generally refer to corresponding parts unless otherwise indicated. The figures are drawn to clearly illustrate the relevant aspects of the implementations and are not necessarily drawn to scale. The edges of features drawn in the figures do not necessarily indicate the termination of the extent of the feature.

### DETAILED DESCRIPTION OF ILLUSTRATIVE IMPLEMENTATIONS

The making and using of various implementations are discussed in detail below. It should be appreciated, however, that the various implementations described herein are applicable in a wide variety of specific contexts. The specific implementations discussed are merely illustrative of specific ways to make and use various implementations, and should not be construed in a limited scope.

Reference to “an implementation,” “one implementation,” “an embodiment,” or “one embodiment” in the framework of the present description is intended to indicate that a particular configuration, structure, or characteristic described in relation to the implementation/embodiment is included in at least one implementation/embodiment. Hence, phrases such as “in one implementation” or “in one embodiment” that may be present in one or more points of the present description do not necessarily refer to one and the same implementation/embodiment. Moreover, particular conformations, structures, or characteristics may be combined in any adequate way in one or more implementations/embodiments. The references used herein are provided merely for convenience and hence do not define the extent of protection or the scope of the implementations/embodiments.

The present disclosure relates to a clock latch system designed to enhance the performance and functionality of integrated circuits. In particular, the system incorporates an arrangement of components that allows for the integration of test signals directly into the output driver or state node of the latch. This approach addresses the challenge of maintaining optimal performance and power efficiency while incorporating additional functionalities such as test and scan capabilities, which are necessary for verifying the correct operation of complex circuits during manufacturing and debugging processes.

In the disclosed clock latch system, a front-end circuit is configured to receive and process input signals. This front-end circuit may include a logic gate (may also be referred to as combo or combination gate) designed to process multiple input signals. The processed signals are then stored in a latch circuit connected to the front-end circuit. This latch circuit may include a transmission gate connected to a state node, providing a mechanism for storing the state of the processed signal.

In some implementations, the latch circuit is designed to integrate test signals received from test enable inputs. These test signals may include a test enable (TE) signal and a scan shift enable (SSE) signal, which are needed for controlling the timing of operations within integrated circuits and ensuring proper functionality during testing processes. The system also includes an output driver circuit connected to the latch circuit. In some implementations, this output driver circuit is designed to integrate the test signals received from test enable inputs.

The output driver circuit may comprise a plurality of transistors arranged to form a gate structure. The TE signal and SSE signal can be connected to specific transistors in the output driver circuit, providing a flexible and efficient mechanism for integrating these test signals into the system.

The disclosed clock latch system may also include a clock generation circuit connected to the latch circuit and the output driver circuit. This clock generation circuit is configured to provide clock signals for latch operation.

The disclosed clock latch system and method of operation provide several benefits. By integrating test signals directly into the output driver circuit or latch circuit, the system can improve timing performance while maintaining test and scan functionalities. This approach also allows for better utilization of the front-end logic, potentially leading to significant improvements in timing and power efficiency across various chip designs. Furthermore, the system's flexible design allows for tailored implementations to meet specific timing and power requirements in different parts of the chip design.

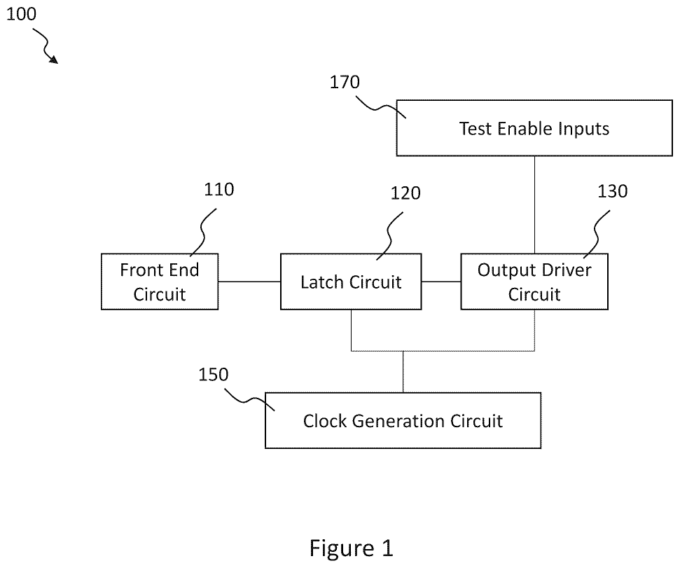

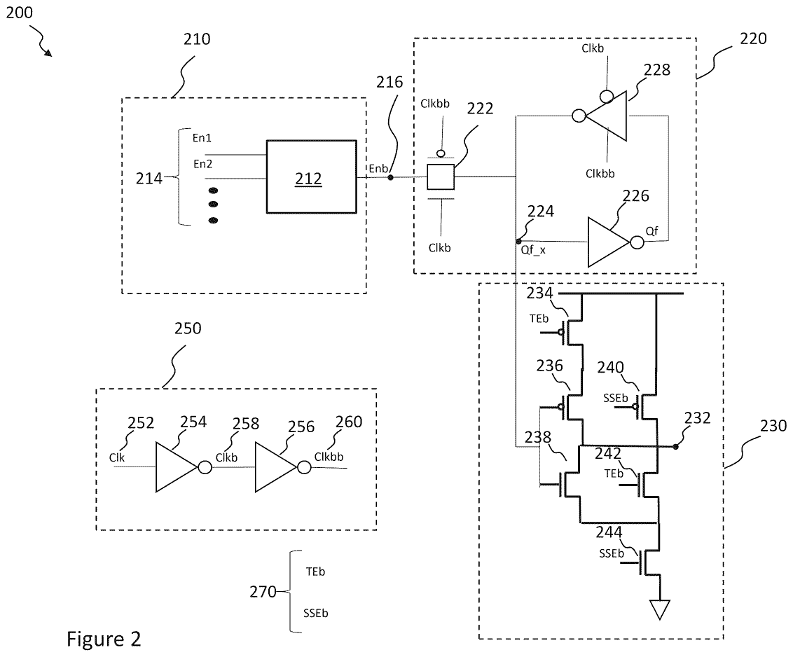

FIG. 1 illustrates a block diagram of a clock latch system 100 according to various implementations. FIG. 1 serves as a high-level representation for the more detailed circuits shown in subsequent FIGS. 2-4. The clock latch system 100 includes several components that work together to implement a clock latch functionality with integrated test capabilities. The system comprises a front-end circuit 110, which is connected to a latch circuit 120. The latch circuit 120 is further connected to an output driver circuit 130. These three components form the main signal path of the clock latch system 100.

The front-end circuit 110 is configured to receive and process input signals. In some aspects, the front-end circuit 110 may include a logic gate designed to process multiple input signals. The latch circuit 120 is configured to store a state of a processed signal. In some cases, the latch circuit 120 may include a transmission gate connected to a state node. The transmission gate is controlled by clock signals, which are provided by a clock generation circuit 150. The clock generation circuit 150 is connected to the latch circuit 120 and the output driver circuit 130, providing necessary clock signals for their operation.

The output driver circuit 130 is connected to the latch circuit 120 and is configured to prepare the signal for output. The output driver circuit 130 may include a gate structure formed by a plurality of transistors. In some implementations, the output driver circuit 130 is also configured to integrate test signals directly into the circuit. These test signals are received via test enable inputs 170, which are connected to the output driver circuit 130. This connection allows for the integration of test signals into the output stage of the clock latch system 100.

The test enable inputs 170 may include a test enable (TE) signal and a scan shift enable (SSE) signal. These signals are used for controlling the timing of operations within integrated circuits and ensuring proper functionality during testing processes. The integration of these test signals into the output driver circuit 130 allows for test functionality without affecting the operation of the front-end circuit 110 or the latch circuit 120.

FIG. 2 illustrates a circuit diagram of the clock latch system 200 with integrated test signals. This figure provides a more detailed view of the system's components and their interconnections, demonstrating the integration of test signals and the potential performance improvements. The clock latch system 200 includes a front-end circuit 210, a latch circuit 220, output driver circuit 230, a clock generation circuit 250, and test enable inputs 270.

The front-end circuit 210 comprises a logic gate 212 with multiple input terminals 214. The input terminals 214 may receive various signals such as enable signals, data signals, or control signals from other parts of the larger circuit or system. These signals could originate from data paths, control logic, or other functional blocks within the integrated circuit. This logic gate 212 can be any inverting logic gate, improving the flexibility and efficiency of the system. The logic gate 212 processes the input signals and produces an enable output 216, which is connected to the latch circuit 220. This configuration allows for the integration of additional logic functionality directly into the clock latch, potentially reducing the overall gate count and improving timing performance.

The latch circuit 220 includes a transmission gate 222 that receives the enable output 216. The transmission gate 222 is connected to a state node 224, which stores the state of the processed signal. The transmission gate 222 may include complementary NMOS and PMOS transistors controlled by the clock signals, allowing bidirectional signal flow when enabled. An inverting buffer 226 is connected to the state node 224, providing an inverted output. A feedback tri-state buffer 228 is connected between the output of the inverting buffer 226 and the state node 224, forming a feedback loop. The feedback tri-state buffer 228 may be implemented using a pair of transmission gates or a combination of transistors that can be switched to a high-impedance state. This feedback loop ensures that the state of the signal is maintained in a stable state for subsequent operations.

Connected to the state node 224, the output driver circuit 230 comprises several transistors (234, 236, 238, 240, 242, 244) arranged in a specific configuration to integrate test signals into the circuit. The arrangement in FIG. 2 is a specific implementation, but other arrangements are within the scope of the present disclosure.

In some implementations, the transistor 234 is a PMOS transistor connected to power supply voltage (VDD) with its gate connected to the TE signal. This connection allows the TE signal to directly control the behavior of the output driver circuit 230 during test operations. In some implementations, the transistor 244 is a NMOS transistor connected to ground (GND) with its gate connected to the SSE signal. This connection allows the SSE signal to directly control the behavior of the output driver circuit 230 during scan test operations.

The transistors 240 and 242 are connected in series between 244 and VDD and are controlled by the test enable (TEb) and scan shift enable (SSEb) signals. This configuration allows these test signals to control the output state during test modes.

The transistors 236 and 238 form a complementary pair (one PMOS and one NMOS) that is controlled by the state node 224 from the latch circuit 220. These transistors drive the output under normal operating conditions when test modes are not active.

This arrangement of transistors allows the output driver circuit 230 to integrate both the main signal path and the test signal controls, enabling efficient switching between normal operation and test modes. The output of the output driver circuit 230 is available at the output node 232. In contrast to related designs where test signals are integrated into the front-end, this approach incorporates test signals, received via test enable inputs 270, directly into the output driver circuit 230. This configuration allows for the integration of test signals into the output stage of the clock latch system 200, improving the overall performance and testability of the system while also enhancing the speed of the main data path.

The clock generation circuit 250 is connected to both the latch circuit 220 and the output driver circuit 230. It includes a clock input 252 connected to a first clock inverter 254, which outputs a first clock output 258 (Clkb). A second clock inverter 256 is connected to the first clock inverter 254 and produces a second clock output 260 (Clkbb). These differential clock signals are used to control the operation of the latch circuit 220 and the output driver circuit 230, ensuring proper timing and synchronization.

The test enable inputs 270 include signals for test enable (TEb) and scan shift enable (SSEb). The “b” suffix in signals names (e.g., Clkb, TEb, SSEb) denotes that they are inverted or “bar” signals, although in some implementations, non-inverted signals may be used. The “bb” suffix in signal names denotes that the signals are double inverted. These signals are integrated into the output driver circuit 230, specifically controlling transistors 234, 236, 240, 242, and 244. The TE signal is used to shut off gaters during testing, while the SSE signal is used to turn on gaters during scan shift. In this context, a “gater” refers to a clock gating circuit, which is used to selectively enable or disable the clock signal to specific parts of the digital circuit, primarily to reduce power consumption by preventing unnecessary switching activity. This arrangement ensures that test and scan control have final control in gater enablement which is needed for the proper functioning of the testing process. By moving these signals to the output driver circuit 230, the design maintains test functionality while freeing up the front-end circuit 210 for logic optimization.

The TE and SSE signals facilitate different types of testing and scanning operations. When TE is active, it disables normal clock gating, allowing testers to directly control clock signals for specific test patterns. This is used for stuck-at fault testing and delay fault testing. The SSE signal, when active, enables scan chain operation, allowing test patterns to be shifted into the flip-flops of the circuit. This is used for structural testing, where specific internal states need to be set up or observed. By integrating these signals into the output driver circuit 230, the design allows for seamless switching between functional and test modes without impacting the main data path timing.

The operation of the clock latch system can be described as follows: Input signals are received and processed by the logic gate 212 in the front-end circuit 210. The processed signal (enable output 216) is then passed to the latch circuit 220. The transmission gate 222, controlled by differential clock signals from the clock generation circuit 250, allows the signal to be stored in the state node 224. The inverting buffer 226 and feedback tri-state buffer 228 work together to maintain the signal state.

The output driver circuit 230 then prepares the signal for output, integrating the test signals (TE and SSE) in the process. This integration allows for control over the output during testing procedures without affecting the main signal path through the front-end and latch circuits 210 and 220.

The design of this clock latch system 200 offers several. By moving the test signal integration to the output driver circuit 230, it allows for greater flexibility in the front-end circuit 210, reducing gate delays and improving overall system performance. Additionally, this configuration maintains or potentially enhances the speed of the main data path while still providing robust test capabilities, addressing a challenge in clock latch design for high-performance systems.

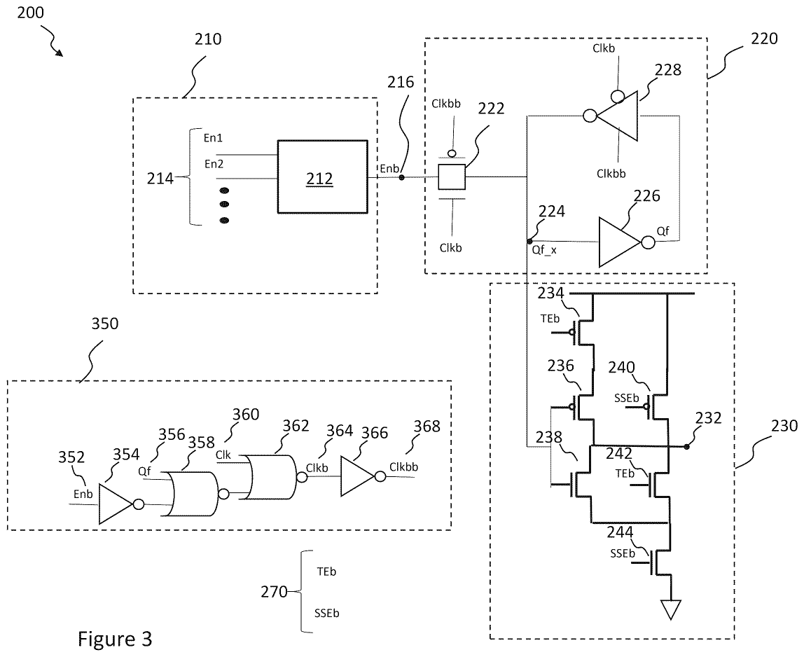

FIG. 3 illustrates a variation of the clock latch system including power reduction functionality. The circuit diagram 300 is similar to FIG. 2 with this circuit including a clock generation circuit 350. The clock generation circuit 350 includes an enable input 352 connected to a first inverter 354. In some implementations the enable input 352 is the enable output 216. The output of the first inverter 354 is connected to a latched value 356, which feeds into a first NOR gate 358. A clock input 360 is connected to a second NOR gate 362. The output of the second NOR gate 362 produces an inverted clock 364 at an output node 366. A final inverter produces a double inverted clock 368. This clock generation circuit 350 implements a power-saving mechanism by gating the clock signal. The first NOR gate 358 compares the current enable input (inverted by 354) with the previous latched value 356. If both are low (indicating no change in the enable signal), the second NOR gate 362 blocks the clock signal, preventing unnecessary transitions in the latch circuit. This gating occurs for consecutive low enable signals, effectively reducing power consumption when the latch's input remains stable at a low level over multiple clock cycles.

This clock generation circuit 350 includes gating for low power operation. It provides the necessary clock signals for the operation of the latch circuit 220 and the output driver circuit 230, ensuring that the latch circuit 220 captures and holds the state of the signal at the appropriate times, and that the output driver circuit 230 drives the output signal in a timely manner. The power reduction functionality is configured to gate clock signals for consecutive input signal values, helping to reduce the overall power consumption of the clock latch system.

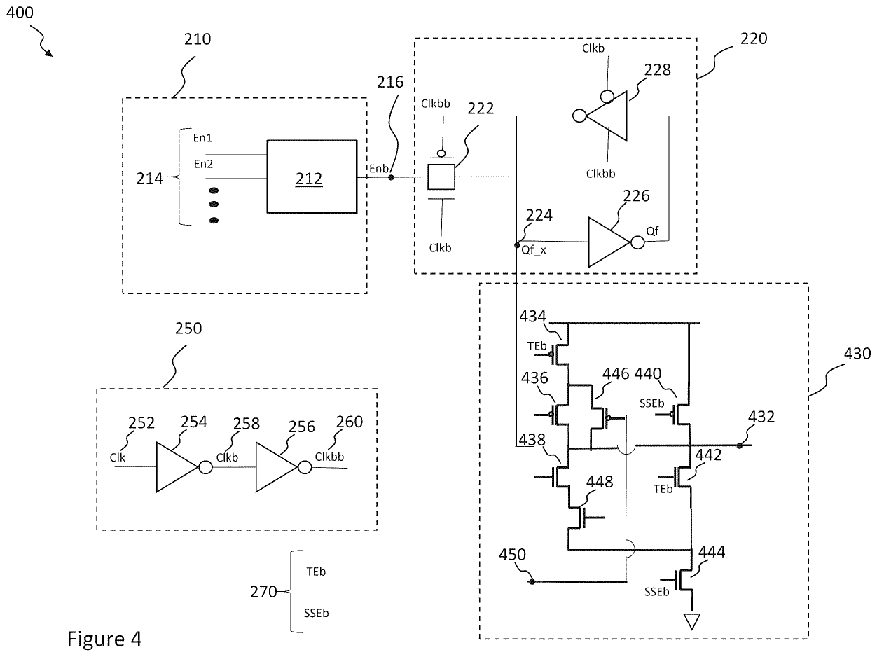

FIG. 4 illustrates another variation of the clock latch system and includes a different implementation of the output driver circuit. The circuit diagram 400 is similar to FIG. 2 with this circuit including an output driver circuit 430. The circuit diagram 400 includes the front-end circuit 210, the latch circuit 220, the output driver circuit 430, the clock generation circuit 250, and the test enable inputs 270.

The output driver circuit 430 is connected to the state node 224 and comprises several transistors (434, 436, 438, 440, 442, 444, 446, 448) arranged in a specific configuration. The output of this driver is available at the output node 432. Details of the output driver circuit 430 that are similar to the output driver circuit 230 are not repeated herein. The transistors 446 and 448 are used to ‘OR’ another set of enable signals generated from another latch front end and latch circuit similar to the front-end and latch circuits 210 and 220. In some implementations, the clock generation for multiple front-end latch circuits share a common clock generation circuit 250. This implementation further increases timing and power efficiency of the output driver circuit 430 while it increases the area needed for the circuit.

An additional feature of this output driver circuit 430 is its ability to combine multiple enable signals from multiple front-end latches (e.g., the front-end and latch circuits 210 and 220). This can be achieved by connecting additional input nodes, such as additional input node 450, to the output driver circuit 430. Each additional input node 450 can receive an enable signal from a separate front-end latch, allowing the output driver circuit 430 to combine these signals and produce a single output. This feature can further enhance the performance of the clock latch system by reducing upstream data path delay. By combining multiple enables, the system can effectively process signals from different sources without introducing additional delay stages. This multi-enable capability also provides designers with greater flexibility in circuit layout and signal routing, potentially leading to more efficient overall chip designs.

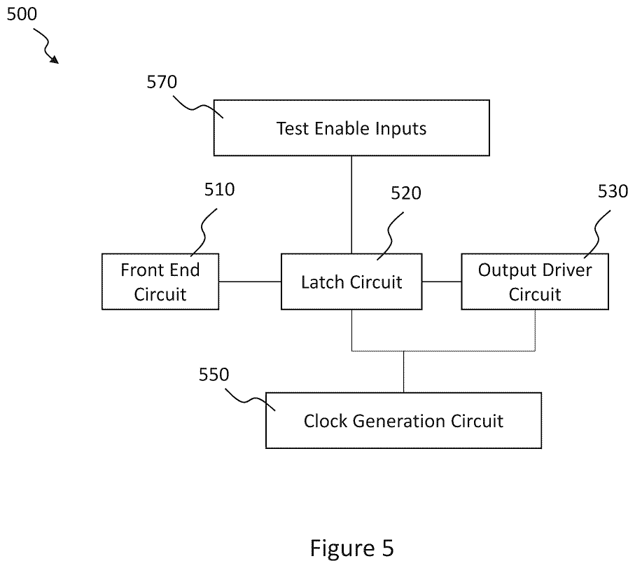

FIG. 5 illustrates a block diagram of another clock latch system 500, which serves as a high-level representation for the more detailed circuits shown in subsequent figures. This system includes a front-end circuit 510, a latch circuit 520, an output driver circuit 530, a clock generation circuit 550, and test enable inputs 570. In this implementation, the test enable inputs 570 are integrated into the latch circuit 520.

Many parts of this implementation is similar to the implementation of FIGS. 1-4 described above and the description is not repeated herein. In this implementation, the test enable inputs 570 are connected to the latch circuit 520. This arrangement allows for the integration of test signals into the latch circuit.

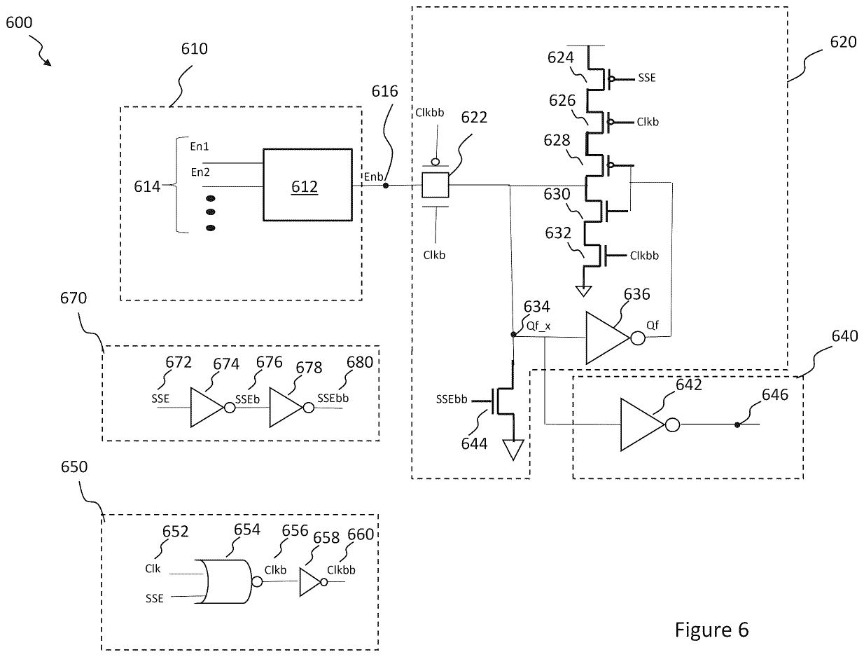

FIG. 6 provides a detailed circuit diagram 600 of the clock latch system introduced in FIG. 5. The circuit diagram 600 includes a front-end circuit 610, a latch circuit 620, an output circuit 640, a clock generation circuit 650, and test enable inputs 670. This configuration demonstrates an alternative approach to integrating test signals into the clock latch system.

The front-end circuit 610 may be similar to the front-end circuit 210 described above and details are not repeated herein. The front-end circuit 610 includes a logic gate 612 with multiple input terminals 614. These input terminals may receive various signals such as enable signals, data signals, or control signals from other parts of the larger circuit or system, similar to the arrangement in FIG. 2. The logic gate 612 processes the input signals and produces an enable output 616. This enable output 616 is connected to the latch circuit 620. The ability to use any inverting logic gate for 612 allows for logic optimization and improved timing performance in the front-end circuit 610.

The latch circuit 620 includes a transmission gate 622 that receives the enable output 616. The transmission gate 622 is connected to a state node 634, which is followed by a latch buffer 636. The state node 634 stores the current state of the processed signal, while the latch buffer 636 helps to stabilize the signal. A feedback path is present between the output of the latch buffer 636 and the state node 634, forming a feedback loop to maintain the stored state.

The latch circuit incorporates several transistors (624, 626, 628, 630, and 632) in a specific configuration to integrate test signals into the circuit. The arrangement in FIG. 6 is a specific implementation, but other arrangements are within the scope of the present disclosure.

In some implementations, the transistors 624, 626, 628, 630, and 632 are series connected between ground and VDD. In some implementations, the transistor 624 is a PMOS transistor with its gate connected to the SSE signal. This connection allows the SSE signal to directly control the behavior of the latch during scan test operations.

In some implementations, the transistor 626 is also a PMOS transistor and is series connected to transistor 624 and has its gate is connected to the Clkb signal (inverted clock) and the transistor 632 is an NMOS transistor with its gate connected to the Clkbb signal (double inverted clock). These transistors are the clock inputs for the latching operation.

Transistors 628 (PMOS) and 630 (NMOS) both have their gates coupled to the output of latch buffer 636. These transistors form a complementary pair that serve as part of the feedback mechanism. In some implementations, transistors 628 and 630 create a weak keeper circuit that helps maintain the state of the latch when the transmission gate is off, improving the stability of the stored value.

This configuration of transistors allows for a high degree of control over the latch's operation. During normal operation, the transistors 626 and 632 controls the writing of new values into the latch based on the clock signals. The feedback mechanism using transistors 628 and 630 helps maintain the state when the transmission gate is off.

The latch circuit 620 also includes a transistor 644. The transistor 644 is connected between ground and the state node 634 and has its gate connected to SSEbb (double inverted SSE). The transistors 624 and 644 enable the integration of the Scan Shift Enable signal directly into the latch circuit 620. These transistors act as switches, controlling whether the normal latch output or a scan input is propagated to the output terminal during test operations.

The test enable inputs 670 include an SSE input 672 and optionally a TE input in this configuration (not explicitly labeled in this figure). The SSE input 672 is connected to a series of inverters (674, 678) to produce inverted SSE 676 and double inverted SSE 680. These multiple versions of the SSE signal (non-inverted, inverted, and double inverted) provide the necessary control signals for various parts of the circuit, ensuring proper timing and operation during both normal and test modes. These signals are integrated into the latch circuit 620, allowing for precise control of the latch's behavior during test operations. This integration of test signals into the latch circuit, rather than the output driver as seen in FIG. 2, represents a different approach to incorporating test functionality.

During scan test operations, transistors 624 and 644 are be activated by the SSE signal. SSE is usually low during functional mode. When it turns on, it could be asynchronous, but this implementation of the latch circuit 620 solves that issue by driving output high immediately. In addition, because the transistor 644 gated connected to SEEbb, the pull down from transistor 644 is delayed the by 2 gates to ensure there is no fight between Enb and Qf_x.

The arrangement of these transistors allows the latch to switch between normal operation and test modes, improving the overall testability of the system while maintaining efficient normal operation.

The output circuit 640 comprises an output inverter 642 connected to the state node 634 and an output terminal 646. The output of the latch buffer 636 is connected to the input of the output inverter 642, which drives the output terminal 646.

The clock generation circuit 650 includes a clock input 652, a NOR gate 654, and a clock inverter 658. The NOR gate 654 generates an inverted clock 656, while the clock inverter 658 produces a double inverted clock 660. These clock signals are used to control the operation of the latch circuit 620 and the output circuit 640. The use of a NOR gate in the clock generation circuit allows for the integration of the SSE signal directly into the clock path. This configuration enables the circuit to effectively control clock gating during scan operations.

Table 1 illustrates a truth table for the clock generation circuit 650, showing the relationships between the SSE, Clk, and Clkb signals:

TABLE 1

| SSE | Clk | Clkb |
|---|---|---|
| 0 | 0 | 1 |
| 0 | 1 | 0 |
| 1 | 0 | 0 |
| 1 | 1 | 0 |

The truth table demonstrates the behavior of the Clkb signal in response to different combinations of SSE and Clk inputs. When SSE is 0, Clkb is the inverse of Clk. However, when SSE is 1, Clkb remains 0 regardless of Clk's state. This behavior aligns with the circuit's operation, where SSE controls the clock's activity to facilitate proper timing during scan operations. This truth table highlights the critical role of the SSE signal in controlling the clock behavior during test modes, effectively enabling or disabling the clock as needed for scan shift operations.

The design of this clock latch system offers several advantages. By integrating the SSE signal into both the latch circuit and the clock generation circuit, it provides a comprehensive approach to controlling the latch behavior during test operations. This configuration allows for efficient switching between normal operation and scan test modes, improving the testability of the overall system.

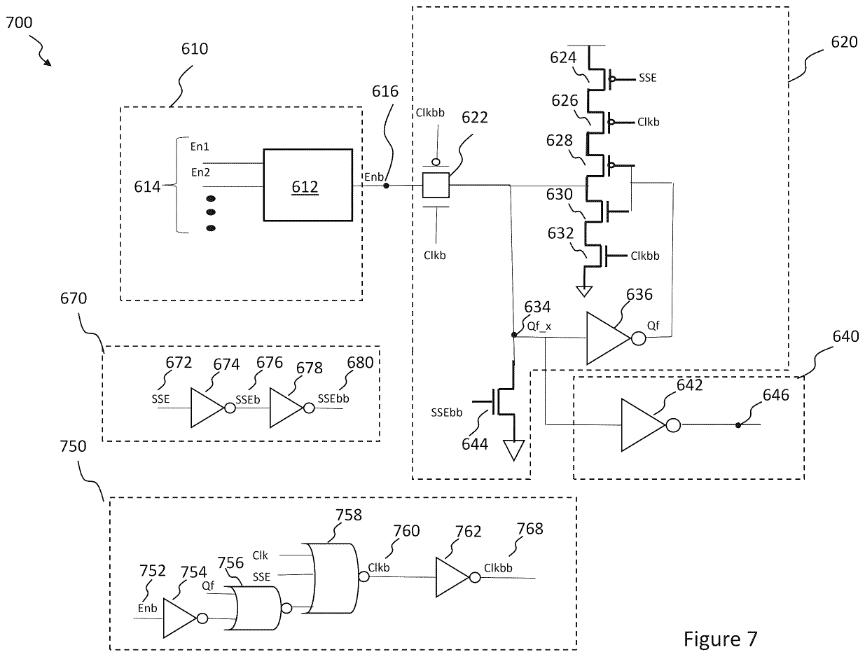

FIG. 7 illustrates a variation of the circuit in FIG. 6, with added power reduction functionality. The circuit diagram 700 includes a front-end circuit 610, a latch circuit 720, an output circuit 740, a clock generation circuit 750, and test enable inputs 770.

The front-end circuit 610 remains the same as in FIG. 6, with a logic gate 612 processing multiple input signals and producing an enable output 616. The latch circuit 720 and output circuit 740 maintain similar structures to those in FIG. 6, with the transmission gate 722, state node 724, inverting buffer 726, and feedback tri-state buffer 728 in the latch circuit, and the output inverter 742 and SSE transistor 744 in the output circuit.

The clock generation circuit 750 includes power reduction functionality. This circuit comprises a enable input 752 which is connected to the enable output 616. This enable input 752 is input to a first clock inverter 754. The first clock inverter 754 is output to a first NOR gate 756. The first NOR gate 756 compares the current state of the enable signal (Enb) with its previous state and outputs to a second NOR gate 758. If both states are low, indicating no change in the enable signal, the second NOR gate 758 gates the clock signal. The output of the second NOR gate outputs an inverted enable 760 which is input to a second clock inverter 762 that outputs a double inverted clock 768. This arrangement prevents the propagation of the clock when the enable signal remains low for consecutive cycles, thereby reducing power consumption. This implementation is particularly effective in scenarios where the enable signal frequently remains low for multiple clock cycles, such as in idle or low-activity states of the circuit. The power reduction functionality in the clock generation circuit 750 is configured to gate clock signals for consecutive input signal values. This can be implemented using various logic gates, such as the NOR gates shown in this figure, depending on the specific requirements of the system. The purpose of this functionality is to reduce the power consumption of the clock latch system when the input values remain constant over multiple clock cycles, making it more energy-efficient.

The test enable inputs 770 maintain a similar structure to FIG. 6, with the SSE input 772 going through a series of inverters (774, 778) to produce inverted SSE 776 and double inverted SSE 780. The TE input 782 follows a similar pattern, with inverters producing inverted TE 786 and double inverted TE 790.

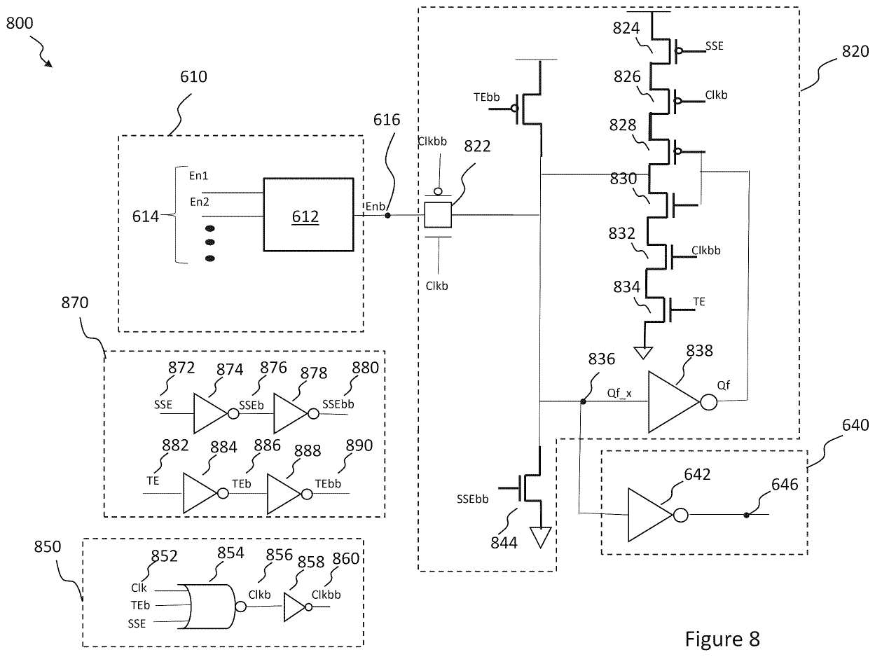

FIG. 8 presents another variation of the clock latch system, with changes to the latch circuit structure. The circuit diagram 800 includes a front-end circuit 610, a latch circuit 820, an output circuit 640, a clock generation circuit 850, and test enable inputs 870.

The latch circuit 820 in this figure is similar to FIG. 6 but also includes a transistor in the series connected stack that is gate connected to TE signal. In some implementations, a transistor 834 is an NMOS transistor with its gate connected to the TE signal. This connection allows the TE signal to directly control the behavior of the latch during test operations.

The latch circuit 820 further includes a transmission gate 822 and several transistors (824, 826, 828, 830, 832, 834, and 844) connected to form a latch structure. The transistors 824, 826, 828, 830, 832, and 844 are similar to the transistors 624, 626, 628, 630, 632, and 644 described above. A state node 836 is connected to these transistors and feeds into a latch inverter 838. This configuration allows for the direct integration of both SSE and TE into the latch circuit.

The output circuit 640 maintains a similar structure to previous figures, with an output inverter 642 connected to the state node 836 and an output terminal 646.

The test enable inputs 870 include both SSE and TE signals, each with their respective inverter chains. The SSE input 872 goes through inverters to produce inverted SSE 876 and double inverted SSE 880, while the TE input 882 produces inverted TE 886 and double inverted TE 890.

The clock generation circuit 850 is similar to the one in FIG. 6 but also includes the TE signal. The clock generation circuit 850 includes a clock input 852 that feeds into a NOR gate 854. Unlike the circuit in FIG. 6, this NOR gate 854 has an additional input: the TEb (Test Enable bar) signal. This addition allows the circuit to control clock generation based on both scan and test modes. The output of the NOR gate 854 produces an inverted clock 856. A subsequent clock inverter 858 then generates a double inverted clock 860. This arrangement enables more clock control, where both the SSE and TE signals can influence the clock behavior. Specifically, the clock can be gated (prevented from toggling) when either the scan mode is active (SSE is high) or the test mode is inactive (TEb is low), providing greater flexibility in controlling the circuit's behavior during different operational and test scenarios.

Table 2 presents a truth table for the clock generation circuit 850, illustrating the relationships between the SSE, TEb, Clk, and Clkb signals:

TABLE 2

| SSE | TEb | Clk | Clkb |
|---|---|---|---|
| 0 | 0 | 0 | 1 |
| 0 | 0 | 1 | 0 |
| 0 | 1 | 0 | 0 |
| 0 | 1 | 1 | 0 |
| 1 | 0 | 0 | 0 |
| 1 | 0 | 1 | 0 |
| 1 | 1 | 0 | 0 |
| 1 | 1 | 1 | 0 |

This truth table shows how Clkb responds to various combinations of SSE, TEb, and Clk inputs. When SSE is 0 and TEb is 1, Clkb mirrors Clk. However, when SSE is 1 or when both SSE and TEb are 0, Clkb remains 0 regardless of Clk's state. This behavior reflects the circuit's operation, where SSE and TEb work together to control clock activity during different test and operational modes.

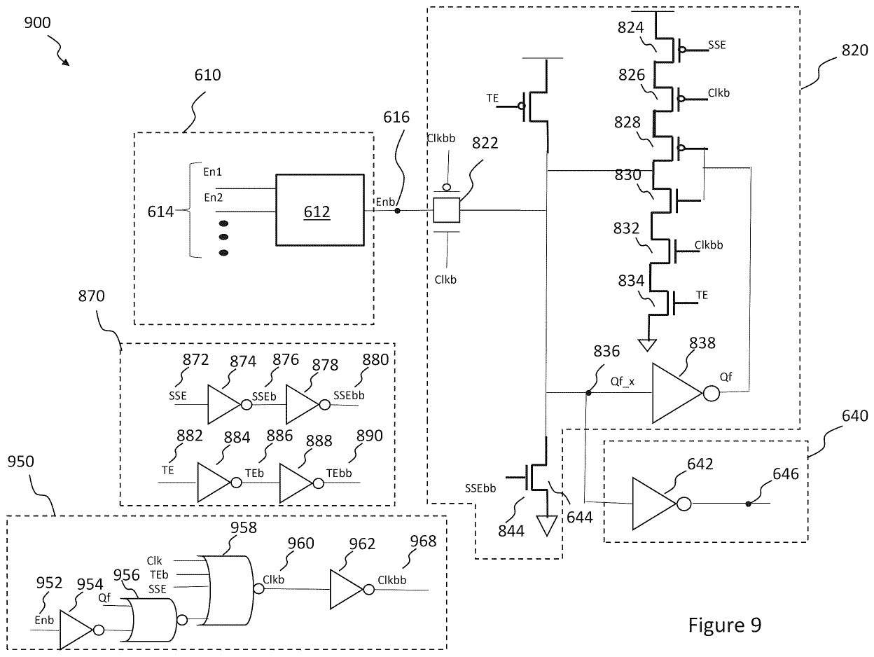

FIG. 9 illustrates a variation with further modifications to the clock generation circuit. The circuit diagram 900 includes components similar to FIG. 8, but with a different clock generation circuit 950.

The clock generation circuit 950 in this figure represents a low power implementation. It includes an enable input 952, a first clock inverter 954, a first NOR gate 956, a second NOR gate 958, a second clock inverter 962, an inverted clock 960, and a double inverted clock 968. This clock generation circuit 950 is similar to the clock generation circuit 750 described above, except that this one also includes a test enable signal TEb input to the second NOR gate 958.

This clock generation circuit 950 is designed to improve power efficiency. The arrangement allows for gating of clock signals for consecutive 0s. The first NOR gate 956 compares the current input state with the previous state stored in the latch. If both states are 0, the second NOR gate 958 gates the clock signal, preventing unnecessary transitions and thus reducing power consumption.

Although the power reduction clock generation circuits 350, 750, and 950 show the implementations for gating consecutive 0s, similar circuits using NAND gates can be designed for gating consecutive 1s, or XNOR gates for gating both consecutive 0s and is. For instance, replacing the NOR gates with NAND gates would create a circuit that gates the clock for consecutive 1s. Using an XNOR gate as the first stage would allow gating for both consecutive 0s and 1s. The choice between these implementations depends on the specific power reduction requirements of the system and the expected signal patterns in different parts of the chip.

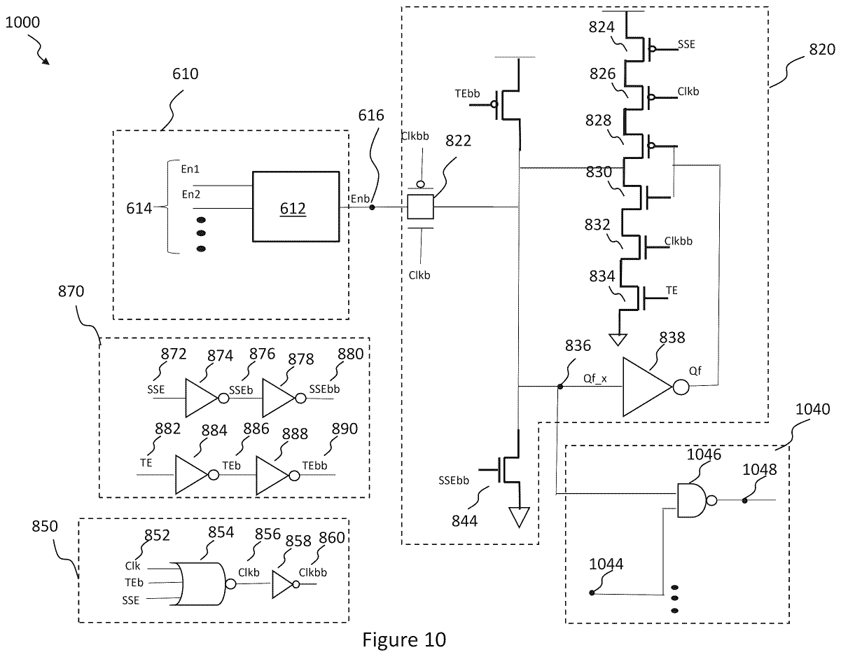

FIG. 10 presents another variation of the clock latch system, focusing on enhancements to the output circuit. The circuit diagram 1000 includes a front-end circuit 610, a latch circuit 820, an output driver circuit 1040, a clock generation circuit 850, and test enable inputs 870.

The output driver circuit 1040 includes an additional input node 1044, and a NAND gate 1046. The NAND gate 1046 combines signals from the latch circuit 820 (the state node 836) and the additional input node 1044. This configuration allows the output driver circuit 1040 to combine multiple enable signals from multiple front-end latches. By providing this capability, the system can reduce upstream data path delay, thereby improving overall system performance.

The latch circuit 820, clock generation circuit 850, and test enable inputs 870 in this figure maintain similar structures and functionalities as described in FIG. 8.

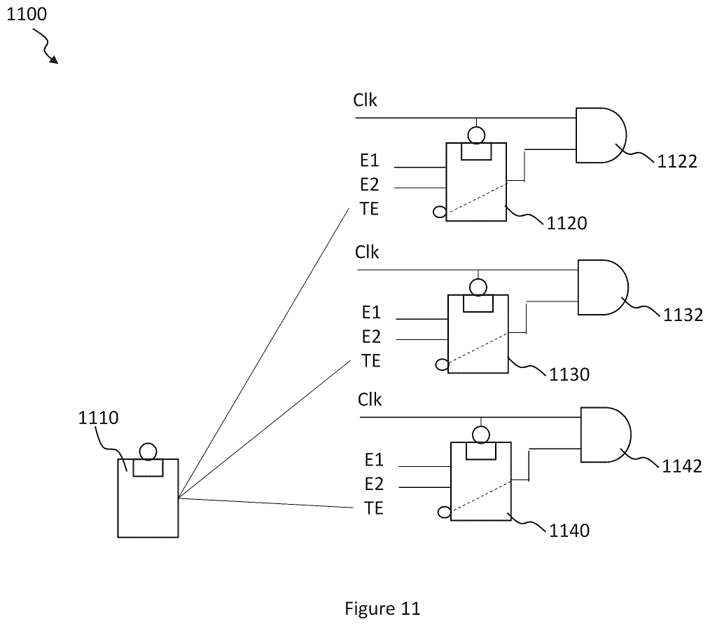

FIG. 11 illustrates a scheme for pre-latched test signals in a clock latch system 1100. FIG. 11 shows an implementation where a separate latch is used to pre-latch the TE signal before it is distributed to multiple clock latches 1120, 1130, and 1140.

A pre-latch circuit 1110 receives and latches the TE signal, ensuring its stability before distribution. This arrangement helps prevent potential glitches in the TE signal from propagating to multiple clock latches, thereby improving the stability and reliability of the test signal integration.

The clock latches (1120, 1130, 1140) each receive a Clk signal and two enable signals (E1 and E2). The pre-latched TE signal from circuit 1110 is distributed to these clock latches. The output of each clock latch is connected to an AND gate (1122, 1132, 1142). These AND gates combine the latch output with the clock signal, allowing for controlled clock gating based on the latch state and test conditions.

This arrangement of clock latches allows for fine-grained control over clock distribution. The AND gates can effectively gate the clock signal based on the state of the latch and the pre-latched TE signal, providing a mechanism to selectively enable or disable clock signals to different parts of the circuit during both normal operation and test modes.

By pre-latching the TE signal, the system can ensure that any changes or potential glitches in the TE signal are captured and stabilized before being distributed to the clock latches. This approach can be particularly beneficial in maintaining signal integrity during functional mode operations and preventing unwanted state changes due to noise or other signal disturbances.

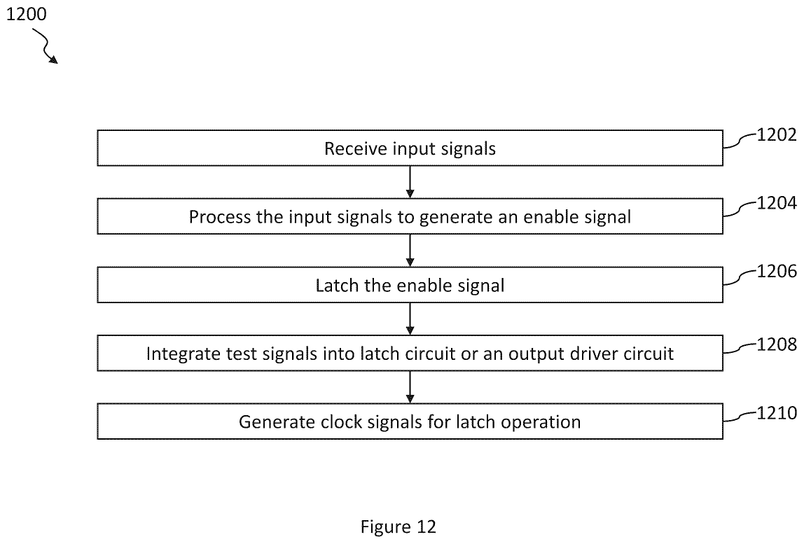

FIG. 12 illustrates a flowchart of a method 1200 for operating a clock latch system with integrated test signals according to various embodiments.

Step 1202 includes receiving input signals at a front-end circuit. In some aspects, the front-end circuit may include a logic gate designed to process multiple input signals.

Next, step 1204 processes the input signals to generate an enable signal. In some cases, the processing of the input signals may involve combining multiple input signals using a logic gate in the front-end circuit.

Next, step 1206 is latching the enable signal. In some implementations, the enable signal is stored in a state node of a latch circuit. The latch circuit may include a transmission gate connected to the state node, providing a reliable mechanism for storing the state of the processed signal. In some cases, the latch circuit may also include a feedback tri-state buffer connected between an output of an inverting buffer and the state node, forming a feedback loop. This feedback loop ensures that the state of the signal is maintained in a stable state for subsequent operations.

Step 1208 integrates test signals directly into an output driver circuit connected to the latch circuit. In some aspects, the output driver circuit may comprise a plurality of transistors arranged to form a gate structure. The test signals, which may include a TE signal and an SSE signal, are connected to transistors in the output driver circuit. This configuration allows for the integration of test signals into the output stage of the clock latch system, improving the overall performance and testability of the system.

Step 1210 includes generating clock signals for latch operation. This may include using a clock generation circuit connected to a latch circuit and an output driver circuit. In some embodiments, the clock generation circuit may include power reduction functionality configured to gate clock signals for consecutive input signal values. This power reduction functionality can help to reduce the power consumption of the clock latch system, making it more energy-efficient.

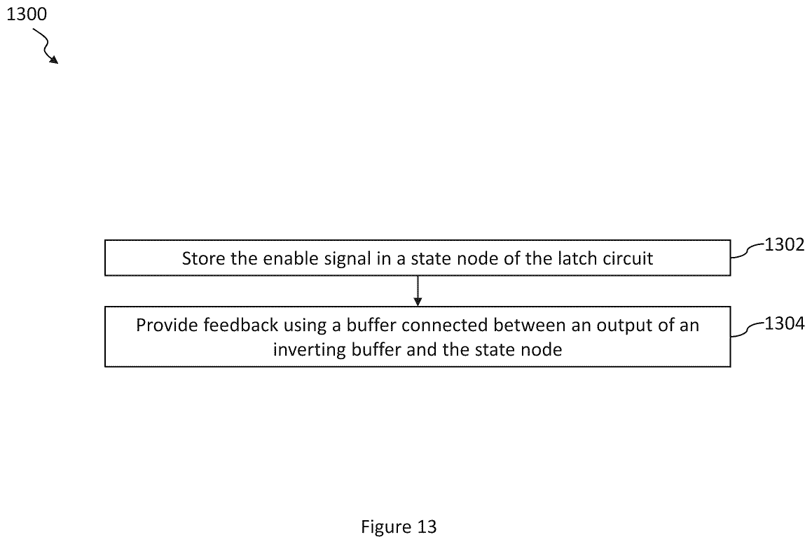

FIG. 13 illustrates a flowchart for a method 1300 of operating a clock latch system according to various implementations. The method 1300 comprises two steps that describe the operation of the latch circuit. The steps of FIG. 13 may be a part of the step 1206 from FIG. 12.

Step 1302 includes storing the enable signal in a state node of the latch circuit. In some implementations, this step represents the initial capture of the enable signal within the latch structure. The state node may be connected to a transmission gate and several transistors arranged to form the latch structure.

Next, step 1304 includes providing feedback using a buffer connected between an output of an inverting buffer and the state node. In some implementations, this feedback mechanism helps maintain the stored state within the latch circuit. The feedback buffer may be a tri-state buffer, allowing for controlled feedback based on clock signals.

In some implementations, the feedback mechanism enhances the stability of the stored signal, improving the reliability of the latch circuit. The use of an inverting buffer in the feedback path helps to maintain signal integrity and reduce the risk of signal degradation over time.

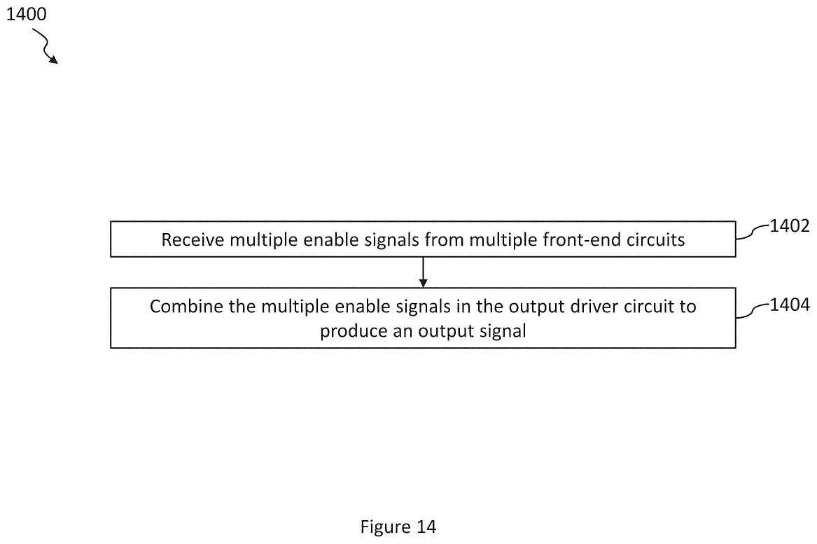

FIG. 14 illustrates a flowchart for a method 1400 of processing multiple enable signals in a clock latch system according to various implementations.

Step 1402 includes receiving enable signals from multiple front-end circuits. In some implementations, this step represents the initial input stage of the process, where various enable signals are collected from different sources within the system. The front-end circuits may include logic structures designed to process and generate enable signals based on various input conditions.

Next, step 1404 includes combining the multiple enable signals in the output driver circuit to produce an output signal. In some implementations, this step represents the processing and consolidation of the various input signals into a single output. The output driver circuit may comprise a complex gate structure or a series of transistors arranged to efficiently combine and process the multiple enable signals.

In some implementations, the combination of multiple enable signals in the output driver circuit may allow for more flexible and efficient operation of the clock latch system. This approach may reduce upstream datapath delay by consolidating logic operations in the output stage rather than in earlier stages of the circuit.

Although FIGS. 12, 13, and 14 illustrate examples of methods, in some implementations, these methods may include additional steps, fewer steps, different steps, or differently arranged steps than those depicted in FIGS. 12, 13, and 14. Additionally, or alternatively, two or more of the steps of the methods 1200, 1300, and/or 1400 may be performed in parallel.

Throughout all these variations (FIGS. 1-14), the fundamental operation of the clock latch system remains consistent. Input signals are processed by the front-end circuit, stored in the latch circuit, and then output through the output driver circuit. The integration of test signals (TE and SSE) allows for comprehensive testing and scan capabilities without significantly impacting the main signal path or degrading performance during normal operation.

The power reduction features introduced in some variations (particularly in FIGS. 3, 7, and 9) help to minimize power consumption, especially in scenarios where the latch state remains unchanged for consecutive clock cycles.

These various implementations of the clock latch system offer flexibility in design, allowing for optimization based on specific requirements such as performance, power efficiency, or test coverage. The ability to integrate test signals directly into either the output driver or the latch circuit provides options for designers to choose the most suitable configuration for their particular application.

The described clock latch system and its variations offer several unique benefits. By integrating test signals directly into either the output driver circuit or latch circuit, the system achieves improved timing performance while maintaining robust test and scan functionalities. This novel approach allows the front-end logic to be utilized for actual logic operations rather than test signal integration, potentially leading to significant improvements in timing and power efficiency across various chip designs. The flexibility to choose between output driver integration (as in FIGS. 1-4) and latch circuit integration (as in FIGS. 5-10) of test signals is a key innovation, allowing designers to optimize for specific performance requirements in different parts of the chip. Furthermore, the system's adaptable design, including variations for power reduction and multi-enable combination, provides a versatile solution that can be tailored to meet diverse timing, power, and functional requirements in modern integrated circuit designs.

It should be understood that the various implementations described in FIGS. 1-14 are not mutually exclusive and can be combined to create additional implementations that leverage multiple advantages. For example, the low power clock generation circuit described in FIG. 3 can be integrated with the multiple input capability of the output driver shown in FIG. 4. Similarly, the power reduction functionality illustrated in FIG. 7 or FIG. 9 could be incorporated into any of the other implementations. The latch circuit with integrated test signals (as in FIG. 8) could be used in conjunction with the multi-enable output circuit of FIG. 10. These combinations allow for customized implementations that can be optimized for specific requirements such as maximum power efficiency, highest performance, or greatest flexibility in testing and operation.

The practical applications of this clock latch system are extensive in the field of integrated circuit design. In high-performance processors, the improved timing achieved by freeing up the front-end logic can lead to higher operating frequencies which can enable increased processing power. For mobile devices, the power reduction features (as described in FIGS. 3, 7, and 9) can extend battery life by minimizing unnecessary clock transitions. In complex System-on-Chip (SoC) designs, the ability to combine multiple enables (as shown in FIG. 10) can simplify signal routing and reduce overall chip area. Moreover, the testability provided by the integrated test signals can improve reliability.

While the described implementations showcase several implementations of the clock latch system, numerous alternative implementations are possible within the scope of this invention. For instance, the front-end circuit could be implemented with different types of logic gates beyond the shown gate, such as AND-OR-INVERT (AOI) or OR-AND-INVERT (OAI) structures, to accommodate logic functions. The latch circuit could be modified to use different types of latches, such as pulsed latches or dual-edge triggered latches, to suit specific timing requirements. Alternative power reduction schemes could be implemented in the clock generation circuit, such as using adaptive voltage scaling in conjunction with clock gating. The output circuit could be further optimized for specific load conditions, potentially incorporating slew rate control or dynamic drive strength adjustment. Additionally, the test signal integration could be extended to include other types of test signals beyond TE and SSE, such as BIST (Built-In Self-Test) signals, further enhancing the system's testability.

In an implementation, a clock latch system may include a front-end circuit configured to receive and process input signals. The clock latch system may also include a latch circuit connected to the front-end circuit and configured to store a state of a processed signal. The clock latch system may also include an output driver circuit connected to the latch circuit. The clock latch system may also include test enable signals coupled to at least one of the latch circuit or the output driver circuit. The clock latch system may also include a clock generation circuit connected to the latch circuit.

The described implementations may also include one or more of the following features. The clock latch system where the front-end circuit may include a logic gate configured to process multiple input signals. The clock latch system where the latch circuit may include a transmission gate connected to a state node. The clock latch system where the latch circuit further may include an inverting buffer connected to the state node and a feedback tri-state buffer connected between an output of the inverting buffer and the state node. The clock latch system where the test enable signals may include a test enable (TE) signal and a scan shift enable (SSE) signal. The clock latch system where the output driver circuit may include a plurality of transistors, and where the TE signal and SSE signal are each gate connected to least one of the plurality of transistors in the output driver circuit. The clock latch system where the clock generation circuit includes power reduction functionality configured to gate clock signals for consecutive unchanged input signal values. The clock latch system where the clock generation circuit may include a first NOR gate configured to compare a current enable input with a previous latched value, and a second NOR gate connected to the first NOR gate and configured to gate a clock signal based on an output of the first NOR gate. The clock latch system where the output driver circuit is configured to combine multiple enable signals from multiple latch circuits. The clock latch system where the latch circuit may include: a transmission gate, a state node connected to the transmission gate, a plurality of transistors connected to the state node and configured to form a latch structure, and a latch inverter connected to the state node. The clock latch system may include a pre-latch circuit configured to latch the test enable signals before they are integrated into the at least one of the latch circuit or the output driver circuit. The clock latch system where the output driver circuit may include: a test signal transistor having a gate connected at least one of the test enable signals, and an output terminal connected to the test signal transistor.

In an implementation, a clock latch system may include a front-end circuit having a logic gate with multiple input terminals. The clock latch system may also include a latch circuit connected to the front-end circuit, the latch circuit having a transmission gate configured to receive an enable output from the front-end circuit, a state node connected to the transmission gate, and a plurality of transistors connected to the state node and controlled by at least one test signal. The clock latch system may also include an output circuit connected to the state node. The clock latch system may also include a clock generation circuit connected to the latch circuit, the clock generation circuit configured to control clock gating based on the at least one test signal.

The described implementations may also include one or more of the following features. The clock latch system where the plurality of transistors may include a first transistor connected between a power supply voltage and the state node, the first transistor having a gate connected to a scan shift enable (SSE) signal, a second transistor connected in series with the first transistor, the second transistor having a gate connected to an inverted clock signal, a third transistor connected to the state node and having a gate connected to a latch buffer output, and a fourth transistor connected between ground and the state node, the fourth transistor having a gate connected to a double inverted scan shift enable signal. The clock latch system where the plurality of transistors further may include a fifth transistor connected in series between the first transistor and the state node, the fifth transistor having a gate connected to a test enable (TE) signal, and the clock generation circuit may include a NOR gate having both the SSE signal and the TE signal as inputs for controlling clock gating during both scan and test operations.

In an implementation, a method may include receiving input signals at a front-end circuit. The method may also include processing the input signals to generate an enable signal. The method may also include storing the enable signal in a state node of a latch circuit. The method may also include controlling a plurality of transistors in at least one of the latch circuit or an output driver circuit using at least one test signal. The method may also include generating clock signals for the latch circuit based on the at least one test signal.

The described implementations may also include one or more of the following features. The method where processing the input signals may include receiving multiple input signals at a logic gate of the front-end circuit, and combining the multiple input signals using the logic gate to generate the enable signal. The method where storing the enable signal may include controlling a transmission gate connected to the state node using the clock signals, inverting an output of the state node using an inverting buffer, and providing feedback from the inverting buffer to the state node using a tri-state buffer. The method where generating the clock signals may include comparing a current enable signal value with a previous latched value, and gating the clock signals when the current enable signal value and the previous latched value are unchanged for consecutive clock cycles. The method may include receiving multiple enable signals from multiple front-end circuits, combining the multiple enable signals in the output driver circuit to generate a combined enable signal, and outputting the combined enable signal.

Although the description has been described in detail, it should be understood that various changes, substitutions, and alterations may be made without departing from the spirit and scope of this disclosure as defined by the appended claims. The same elements are designated with the same reference numbers in the various figures. Moreover, the scope of the disclosure is not intended to be limited to the particular implementations described herein, as one of ordinary skill in the art will readily appreciate from this disclosure that processes, machines, manufacture, compositions of matter, means, methods, or steps, presently existing or later to be developed, may perform substantially the same function or achieve substantially the same result as the corresponding implementations described herein. Accordingly, the appended claims are intended to include within their scope such processes, machines, manufacture, compositions of matter, means, methods, or steps.

1. A clock latch system, comprising:
a front-end circuit configured to receive and process input signals;
a latch circuit connected to the front-end circuit and configured to store a state of a processed signal;
an output driver circuit connected to the latch circuit;
test signals coupled to at least one of the latch circuit or the output driver circuit; and
a clock generation circuit connected to the latch circuit.

2. The clock latch system of claim 1, wherein the front-end circuit comprises a logic gate configured to process multiple input signals.

3. The clock latch system of claim 1, wherein the latch circuit comprises:
a transmission gate;
a state node connected to the transmission gate; and
a latch inverter connected to the state node.

4. The clock latch system of claim 3, wherein the latch circuit further comprises a feedback tri-state buffer connected between an output of the latch inverter and the state node.

5. The clock latch system of claim 3, wherein the latch circuit further comprises a plurality of transistors connected to the state node and configured to form a latch structure.

6. The clock latch system of claim 1, wherein the test signals comprise a test enable (TE) signal and a scan shift enable (SSE) signal.

7. The clock latch system of claim 6, wherein the output driver circuit comprises a plurality of transistors, and wherein the TE signal and SSE signal are each gate connected at least one of the plurality of transistors in the output driver circuit.

8. The clock latch system of claim 1, wherein the clock generation circuit includes power reduction functionality configured to gate clock signals for consecutive unchanged input signal values.

9. The clock latch system of claim 8, wherein the clock generation circuit comprises:
a first NOR gate configured to compare a current enable input with a previous latched value; and
a second NOR gate connected to the first NOR gate and configured to gate a clock signal based on an output of the first NOR gate.

10. The clock latch system of claim 1, wherein the output driver circuit is configured to combine multiple enable signals from multiple latch circuits.

11. The clock latch system of claim 1, further comprising:
a pre-latch circuit configured to latch the test signals before they are integrated into the at least one of the latch circuit or the output driver circuit.

12. The clock latch system of claim 1, wherein the output driver circuit comprises:
a test signal transistor having a gate connected to least one of the test signals; and
an output terminal connected to the test signal transistor.

13. A clock latch system, comprising:
a front-end circuit comprising a logic gate with multiple input terminals;
a latch circuit connected to the front-end circuit, the latch circuit comprising:
a transmission gate configured to receive an enable output from the front-end circuit;
a state node connected to the transmission gate; and
a plurality of transistors connected to the state node and controlled by at least one test signal;
an output driver circuit connected to the state node; and
a clock generation circuit connected to the latch circuit, the clock generation circuit configured to control clock gating based on the at least one test signal.

14. The clock latch system of claim 13, wherein the plurality of transistors comprises:
a first transistor connected between a power supply voltage and the state node, the first transistor having a gate connected to a scan shift enable (SSE) signal;
a second transistor connected in series with the first transistor, the second transistor having a gate connected to an inverted clock signal;
a third transistor connected to the state node and having a gate connected to a latch buffer output; and
a fourth transistor connected between ground and the state node, the fourth transistor having a gate connected to a double inverted scan shift enable signal.

15. The clock latch system of claim 14, wherein:
the plurality of transistors further comprises a fifth transistor connected in series between the first transistor and the state node, the fifth transistor having a gate connected to a test enable (TE) signal; and
the clock generation circuit comprises a NOR gate having both the SSE signal and the TE signal as inputs for controlling clock gating during both scan and test operations.

16.-20. (canceled)

21. A clock latch system, comprising:
a front-end circuit comprising a logic gate having multiple input terminals and configured to produce an enable output;
a latch circuit connected to the front-end circuit, the latch circuit comprising:
a transmission gate configured to receive the enable output;
a state node connected to the transmission gate;
an inverting buffer connected to the state node; and
a feedback tri-state buffer connected between an output of the inverting buffer and the state node;
an output circuit connected to the state node, the output circuit comprising a test signal transistor having a gate connected to a scan shift enable (SSE) signal; and
a clock generation circuit connected to the latch circuit, the clock generation circuit comprising power reduction functionality configured to gate a clock signal based on consecutive unchanged values of the enable output.

22. The clock latch system of claim 21, wherein the clock generation circuit comprises:
a first NOR gate configured to compare a current value of the enable output with a previous latched value; and
a second NOR gate connected to an output of the first NOR gate and configured to gate the clock signal based on the output of the first NOR gate.

23. The clock latch system of claim 21, further comprising a test enable input circuit configured to receive the SSE signal and produce an inverted SSE signal and a double inverted SSE signal, wherein the double inverted SSE signal is connected to the gate of the test signal transistor.

24. The clock latch system of claim 21, wherein the output circuit further comprises an output inverter connected between the state node and an output terminal.

25. The clock latch system of claim 21, further comprising a pre-latch circuit configured to latch a test enable (TE) signal before the TE signal is provided to the clock latch system.
